(19) United States
(12) Patent Application Publication
(10) Pub. No.: US 2024/0138269 A1
(43) Pub. Date: Apr. 25, 2024

(54) MULTIMODE SUPERCONDUCTING CAVITY RESONATORS

(71) Applicant: Yale University, New Haven, CT (US)

(72) Inventors: Chan U Lei, Stamford, CT (US); Suhas Ganjam, Fairfield, CA (US); Lev Krayzman, New Haven, CT (US); Robert J. Schoelkopf lll, Madison, CT (US); Luigi Frunzio, North Haven, CT (US)

(73) Assignee: Yale University, New Haven, CT (US)

(21) Appl. No.: 18/277,505

(22) PCT Filed: Feb. 17, 2022
(86) PCT No.: PCT/US2022/016733

§ 371 Date: Aug. 15, 2023

Related U.S. Application Data
(60) Provisional application No. 63/150,955, filed on Feb. 18, 2021.

(51) Int. Cl. H10N 60/80; G06N 10/40; H10N 60/12; H10N 60/85

(52) U.S. Cl. CPC H10N 60/805; G06N 10/40; H10N 60/12; H10N 60/85

(57) ABSTRACT

Techniques are described to construct an electromagnetic resonator by arranging a resonant structure within a super-conducting cavity. The architecture of the design may provide a low loss superconducting cavity resonator that may exhibit multiple modes. The multimode nature of this resonator is produced in part by the resonant structure in such a way that allows the modes of the resonator to be adjusted through adjustment of the resonant structure rather than by having to alter the physical dimensions of the cavity, as would otherwise be required in a conventional superconducting cavity resonator. In some embodiments, the resonant structure may include a suspended superconductor comprising metal and/or metallized parts.

### CROSS-REFERENCE TO RELATED APPLICATIONS

The present application claims the benefit under 35 U.S.C. § 119(e) of U.S. Provisional Patent Application No. 63/150,955, filed Feb. 18, 2021, titled “Multimode Microwave Resonators,” which is hereby incorporated by reference in its entirety.

### GOVERNMENT FUNDING

This invention was made with government support under W911NF-18-1-0212 awarded by United States Army Research Office. The government has certain rights in the invention.

### BACKGROUND

High quality factor superconducting resonators are useful resources for quantum computing due to their long lifetime. Some approaches to quantum computing couple the modes of a superconducting resonator to a qubit, such as a transmon qubit, thereby providing for universal quantum control of the state of the resonator through its interactions with the qubit. The superconducting resonators can be connected into a network with low loss transmission lines, leading to a modular and scalable approach to quantum computing.

### SUMMARY

According to some aspects, an electromagnetic resonator is provided comprising a superconducting microwave cavity, and a resonant structure suspended within the cavity and mechanically supported by the cavity, the resonant structure comprising at least one end that is freely suspended within the cavity.

According to some embodiments, the resonant structure comprises a first portion that extends from a first side of the cavity to a second side of the cavity, the second side opposing the first side, and a second portion that extends from the first portion and includes the at least one end that is freely suspended within the cavity.

According to some embodiments, the resonant structure comprises a dielectric substrate.

According to some embodiments, the dielectric substrate comprises sapphire and/or silicon.

According to some embodiments, the resonant structure comprises a thin film of a superconducting material coating the dielectric substrate.

According to some embodiments, the thin film completely covers the dielectric substrate.

According to some embodiments, the superconducting material comprises aluminum.

According to some embodiments, the method further comprises a non-linear superconducting element arranged within the cavity.

According to some embodiments, the non-linear superconducting element comprises at least one Josephson junction.

According to some embodiments, the non-linear superconducting element is a transmon qubit.

According to some embodiments, the resonant structure is coupled to the cavity via one or more dielectric elements.

According to some embodiments, the resonant structure contacts the cavity.

According to some embodiments, the resonant structure is planar.

According to some embodiments, the resonant structure comprises a lower element and an upper element arranged over the lower element and separated from the lower element by a dielectric material.

According to some embodiments, the lower element comprises a circular portion and wherein the at least one end that is freely suspended within the cavity is arranged within the circular portion.

According to some embodiments, the upper element and the lower element are both planar.

According to some aspects, a method of characterizing a first material using the electromagnetic resonator is provided, wherein the resonant structure comprises the first material, the method comprising measuring at least one internal quality factor of the electromagnetic resonator, and determining at least one material property of the first material based at least in part on the measured at least one internal quality factor.

According to some embodiments, the at least one material property includes one or more of: surface resistance, loss tangent, and seam conductance.

According to some embodiments, the method further comprises measuring a first internal quality factor corresponding to a first type of mode of the electromagnetic resonator, and measuring a second internal quality factor corresponding to a second type of mode of the electromagnetic resonator.

The foregoing apparatus and method embodiments may be implemented with any suitable combination of aspects, features, and acts described above or in further detail below. These and other aspects, embodiments, and features of the present teachings can be more fully understood from the following description in conjunction with the accompanying drawings.

### BRIEF DESCRIPTION OF DRAWINGS

Various aspects and embodiments will be described with reference to the following figures. It should be appreciated that the figures are not necessarily drawn to scale. In the drawings, each identical or nearly identical component that is illustrated in various figures is represented by a like numeral. For purposes of clarity, not every component may be labeled in every drawing.

FIGS. 1A-1B depict different views of an illustrative electromagnetic resonator, according to some embodiments;

FIG. 2 illustrates a manufacturing process for a resonant structure of an electromagnetic resonator, according to some embodiments;

FIG. 3 is a photograph of an illustrative resonant structure arranged within part of a superconducting microwave cavity, according to some embodiments;

FIG. 4 is a flowchart of a method of operating an electromagnetic resonator to determine material properties of a material, according to some embodiments;

FIG. 5A is an exploded view of an illustrative electromagnetic resonator that includes a two-tiered resonant structure, according to some embodiments;

FIG. 5B is a plan view of the two-tiered resonant structure shown in FIG. 5A, according to some embodiments;

FIGS. 6A-6C depict different types of resonant modes of the electromagnetic resonator shown in FIGS. 5A and 5B, according to some embodiments; and

FIGS. 7A-7B depict exploded and cross-sectional plan views, respectively, of an illustrative electromagnetic resonator that includes a non-linear element, according to some embodiments.

### DETAILED DESCRIPTION

One way to improve the performance of a quantum computer that includes superconducting resonators is to reduce losses in the resonators. There are numerous reasons why a superconducting resonator loses energy, including losses from the constituent materials and losses from ports that couple to the transmission lines.

Electromagnetic resonators formed from a superconducting cavity typically have a superior coherence compared with other types of electromagnetic resonators, in part due to their small surface to volume ratio, which makes them comparatively insensitive to surface dielectric loss and/or conductor loss. Small scale quantum devices incorporating a small number of cavities as quantum memories have been demonstrated. However, there are some important drawbacks to cavity resonators. First, superconducting cavity resonators typically are formed from a limited range of available materials and fabrication processes and are mostly made of bulk superconductors using machining processes. This restriction prevents the use of high-quality materials such as single-crystal superconductors or high-quality superconducting thin-films grown on pristine single-crystal substrates, limiting improvements to the coherence of the resonator. In addition, the mode structure and electromagnetic field distribution in a superconducting cavity resonator are a result of the cavity's shape, which limits the types of resonators that can be fabricated.

The inventors have recognized and appreciated techniques to construct an electromagnetic resonator by arranging a resonant structure within a superconducting cavity. The architecture of the design may provide a low loss superconducting cavity resonator that exhibits multiple modes. The multimode nature of this resonator is produced in part by the resonant structure in such a way that allows the modes of the resonator to be adjusted through adjustment of the resonant structure rather than by having to alter the physical dimensions of the cavity, as would otherwise be required in a conventional superconducting cavity resonator. In some embodiments, the resonant structure may include a suspended superconductor comprising metal and/or metallized parts.

According to some embodiments, a resonant structure may be arranged within a superconducting cavity and suspended over an opening within the cavity, with ends of the resonant structure being mechanically supported by the cavity. The ends of the resonant structure may in some cases be attached to the cavity using one or more fasteners. Such fasteners may be removable so that different resonant structures can be inserted and removed from the same cavity.

According to some embodiments, a resonant structure may be fully formed from a metal or may have a fully metallized surface. In such cases, the resonant structure may be shaped to have at least one free end that is unsupported within the cavity. Some conventional resonator designs may utilize a straight stripline suspended within a cavity, however in such a design fully metallizing the stripline would turn it into a transmission line. According to some embodiments of the present disclosure, a resonant structure that is fully formed from a metal, or has a fully metallized surface, may be successfully operated with resonant behavior by the resonant structure having a free end that allows the voltage to be zero at the suspended ends of the resonant structure.

According to some embodiments, an electromagnetic resonator as described herein may provide a high-quality memory for storage of quantum information. In general, conventional superconducting cavities may have long coherence times but are constrained to a single material/process combination and to a single frequency. According to some embodiments, the resonant structure of an electromagnetic resonator as described herein may be made from a different material and/or formed using a different process than the cavity, potentially improving its quality (e.g., increasing the quality factor (“Q factor”) of the resonator), and also allowing the resonant structure to be switched for another resonant structure to produce a resonator with a different frequency, without it being necessary to make a whole new cavity.

According to some embodiments, an electromagnetic resonator as described herein may comprise a resonant structure that exhibits multiple types of resonant modes. In particular, the resonant structure may exhibit different types of modes, i.e., modes having different resonant behavior, such as different electromagnetic field distributions, not merely modes with different resonant frequencies. Such a resonator may be operated in each of these modes to produce measurements that are dependent on material properties of the materials of the resonant structure and/or the cavity (and in some cases other materials within the cavity). As a result, this type of resonator may be useful in characterizing materials.

According to some embodiments, the resonant structure inside the cavity of the electromagnetic resonator may provide a way to tailor the resonator's mode structure and/or electromagnetic field distribution. For example, a half-wave resonator with a wavelength equal to 2L can be formed by suspending a resonant structure formed from a metal strip with length L in the cavity. Another example is to confine the electromagnetic fields by forming the resonant structure from two closely separated elements in the cavity. More complicated mode structure and field distribution can be realized by engineering the configurations of the parts.

According to some embodiments, the resonant structure may comprise any material or materials that can be micromachined (e.g., via precision machining, laser cutting, etching, etc.). For example, the materials may comprise bulk superconductors formed through precision machining and/or single-crystal superconductors formed through laser-cutting. Additionally, or alternatively, the resonant structure may comprise single-crystal dielectric substrates formed through laser-cutting and/or etching, followed by thin-film evaporations (e-beam, sputter, etc.) to cover the parts with one or more materials that are superconducting at operating temperatures. This approach not only opens up an opportunity to access high-quality superconducting materials but may also avoid using any nanofabrication processes that may degrade material quality.

According to some embodiments, if a resonant structure is held by dielectric materials and/or contain exposed dielectrics, the dielectrics could induce additional losses if they are not properly designed. However, the inventors have recognized and appreciated techniques to address this issue, as follows. Since the dielectric loss is due, at least in part, to the absorption of the electric fields in the dielectric materials, it can be suppressed or even eliminated by arranging the dielectrics at the electric field nodes of the modes of the superconductor cavity resonator. This strategy may provide a way to build complicated 3-dimensional resonating structures without sacrificing coherence.

Any one or more of the above-described advantages of the design of a superconductor cavity resonator described herein may result in a resonator that is useful for building complicated quantum devices with high coherence.

Following below are more detailed descriptions of various concepts related to, and embodiments of, techniques to construct an electromagnetic resonator by arranging a resonant structure within a superconducting cavity. It should be appreciated that various aspects described herein may be implemented in any of numerous ways. Examples of specific implementations are provided herein for illustrative purposes only. In addition, the various aspects described in the embodiments below may be used alone or in any combination and are not limited to the combinations explicitly described herein.

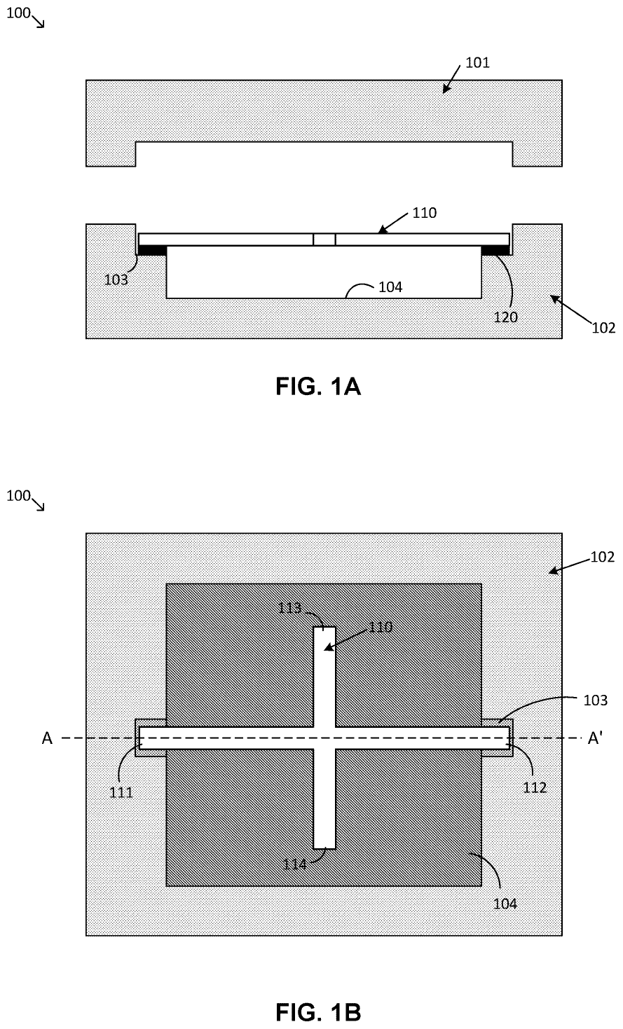

FIGS. 1A-1B depict different views of an illustrative electromagnetic resonator, according to some embodiments. In the example of FIGS. 1A-1B, a resonator 100 comprises a superconducting cavity formed from upper and lower portions 101 and 102. Within the cavity, a resonant structure 110 is arranged, suspended over an opening in the lower portion of the cavity. The resonant structure 110 has a cross shape, including ends 111 and 112 being mechanically supported by the cavity via dielectric material 120, and two free ends suspended within the cavity, 113 and 114. FIG. 1B depicts a plan view of the lower portion of the cavity and the resonant structure, whereas FIG. 1A depicts an exploded view of the upper and lower portions of the cavity through the cross-section A-A′ shown in FIG. 1B. The different flat surfaces 103 and 104 of the lower portion of the cavity 102 are shown with different shading in FIG. 1B merely to visually distinguish them in the drawing.

During operation of the electromagnetic resonator 100, one or more resonant modes of the electromagnetic resonator may be excited (e.g., by delivering an appropriate electromagnetic signal into the cavity using a transmission line coupled to the resonator). It should be noted that, unlike mechanical resonators, the resonant modes of the electromagnetic resonator 100 relate to modes of electromagnetic radiation. As a result, the resonant structure 110 may be understood to be stationary during operation (e.g., unlike a mechanical resonator, which vibrates during operation).

In the example of FIGS. 1A-1B, the cavity 102 may comprise, or may consist of, a superconducting material. As referred to herein, a superconducting material may refer to any material that exhibits superconducting behavior (i.e., carries electrical current with zero resistance) when cooled below a critical temperature. Suitable examples of superconducting materials may include aluminum, niobium, various aluminum alloys including, for instance, 6061 aluminum and 5N5 aluminum, lead, doped silicon carbide and niobium-titanium alloys. In some embodiments, the cavity 102 may be a microwave cavity.

According to some embodiments, each portion of the cavity 101 and 102 may have a mating surface that has been machined or otherwise treated to be smooth so that the portions mate together without gaps when the resonator is assembled. For instance, the lowermost surface of the upper portion 101 and the uppermost surface of the lower portion 102 as shown in FIG. 1A may have been polished, diamond turned, or otherwise fabricated to be smooth. According to some embodiments, each portion of the cavity 101 and 102 may comprise holes for connectors to join the two portions together (e.g., threaded holes for bolts).

In the example of FIGS. 1A-1B, resonant structure 110 may comprise, or may consist of, a superconducting material, including those examples described above. In some embodiments, resonant structure 110 may comprise, or may consist of, a metal. In some embodiments, resonant structure 110 may be formed from a substrate (e.g., a dielectric substrate) onto which a metal has been deposited (e.g., the substrate may be metallized). For instance, a superconducting material may be deposited onto the surface of a substrate such as sapphire or silicon to form the resonant structure 110. In some embodiments, such a metallized structure may be metallized on all surfaces, producing a fully metallized resonant structure. A metallization process as described further below may have an advantage that certain materials may be utilized in the resonator 100 that would otherwise be unavailable for a resonator formed only from a cavity. For example, some materials that are desirable for use in a resonator may be readily formed as a thin film on a substrate, whereas fabricating a cavity using those materials via conventional machining might be difficult or impossible.

According to some embodiments, the resonant structure may comprise a thin film deposited over a substrate, wherein the thin film has a thickness of greater than or equal to 1 nm, greater than or equal to 10 nm, greater than or equal to 100 nm, greater than or equal to 500 nm, greater than or equal to 1 μm, greater than or equal to 5 μm or greater than or equal to 10 μm. According to some embodiments, the resonant structure may comprise a thin film deposited over a substrate, wherein the thin film has a thickness of less than or equal to 50 μm, less than or equal to 10 μm, less than or equal to 5 μm, less than or equal to 1 μm, less than or equal to 500 nm, less than or equal to 100 nm or less than or equal to 10 nm. Combinations of the above-referenced ranges are also possible (e.g., a thin film with a thickness of greater than or equal to 500 nm and less than or equal to 1 μm).

According to some embodiments, resonant structure 110 may be arranged so that the ends 111 and 112 are positioned at nodes of the electric field of the cavity 101/102. The electric field nodes may be determined through analysis of the shape of the internal space of the cavity (e.g., via simulation), and/or via measurements of the cavity during operation.

As described above, the resonant structure may be shaped to have at least one free end that is unsupported within the cavity. In the example of FIGS. 1A-1B, the resonant structure 110 includes two such free ends 113 and 114, although other resonant structures may be envisioned that include a single free end. In addition, more complex shapes than the example of resonant structure 110 may also be envisioned. In some embodiments, resonant structure 110 may be planar as shown in the example of FIGS. 1A-1B, although non-planar shapes may also be contemplated.

According to some embodiments, resonant structure 110 may comprise multiple separate elements that may be arranged proximate to one another (e.g., with one element arranged over another element). In some cases, multiple elements of a resonant structure may all be mechanically supported by the cavity 101/102, whether at the same support location or at different support locations. In some cases, multiple elements of a resonant structure may be arranged with one element arranged over another, and with a spacer (e.g., a dielectric spacer) arranged between the elements.

According to some embodiments, the electromagnetic resonator 100 may comprise multiple different resonant structures within the cavity 101/102. These resonant structures may be separate from one another and may be separately supported by the cavity. For example, the lower portion of the cavity 102 may be arranged to support multiple instances of the resonant structure 110 arranged alongside one another. Because of the way that resonant structure 110 is suspended within the cavity 101/102, including multiple structures in this way may allow for resonator geometries that would be difficult or impossible to create with conventional machining techniques.

According to some embodiments, a length of the resonant structure 110 from end 111 to end 112 may be greater than or equal to 10 mm, greater than or equal to 20 mm, greater than or equal to 30 mm, greater than or equal to 40 mm or greater than or equal to 50 mm. According to some embodiments, a length of the resonant structure 110 from end 111 to end 112 may be less than or equal to 100 mm, less than or equal to 50 mm, less than or equal to 40 mm, less than or equal to 30 mm or less than or equal to 20 mm. Combinations of the above-referenced ranges are also possible (e.g., a length of the resonant structure is greater than or equal to 30 mm and less than or equal to 50 mm).

In the example of FIGS. 1A-1B, dielectric material 120 is arranged beneath ends 111 and 112 of the resonant structure 110 so that, while the resonant structure is mechanically supported by the cavity, there is no mechanical or electrical contact between the resonant structure and cavity. In some cases, however, dielectric losses may be produced due to absorption of the electric field in the dielectric materials. However, in some embodiments the dielectric material 120 may be arranged at the electric field nodes of the modes of the resonator 100, thereby suppressing or eliminating any dielectric losses caused by the presence of the dielectric material 120. Suitable dielectric materials 120 may include polymers such as polytetrafluorethylene (PTFE) or nylon.

Alternatively to the arrangement shown in FIG. 1A, in some embodiments the dielectric material may be omitted so that the resonant structure is supported by and contacts the cavity 101. For instance, the resonant structure 110 may include non-conductive portions that mechanically contact the cavity 101. As such, consistent with the view of FIG. 1B, the resonant structure 110 may directly contact the surfaces 103 on either side of the cavity.

In some embodiments, the resonant structure may be fully metallized except for the ends 111 and 112, which contain only the underlying substrate that is metallized in the remainder of the structure 110. This approach may produce a desired resonant structure while avoiding direct electrical contact between the resonant structure and the cavity 101, and without using an additional dielectric material 120. Resulting electromagnetic modes may be insensitive to losses due to the exposed dielectric substrate by arranging the exposed substrate at the electric field nodes of the mode.

As described above, in some embodiments the resonant structure may be coupled to the cavity (whether via intervening dielectric material or directly) by fasteners that allow the resonant structure to be removed from the cavity. Fasteners may for instance include screws, clips, or any other suitable structure that holds the resonant structure 110 stationary with respect to the cavity. In some cases, the fastener may be selected to minimize any vibrations of the resonant structure that may occur. Suitable fasteners may be formed from a dielectric material such as PTFE or nylon, or may comprise a metal. In the case of a metal fasteners (e.g., a metal screw), negative effects of the inclusion of a metal structure in the cavity may be suppressed or eliminated by avoiding conductive electrical connections between the metal fastener(s) and electrically conductive portions of the resonant structure. For instance, a dielectric portion of the resonant structure as discussed above may contact the cavity, and may be fastened to the cavity with a metal fastener, but without producing an electrical connection between electrically conductive portions of the resonant structure and the cavity.

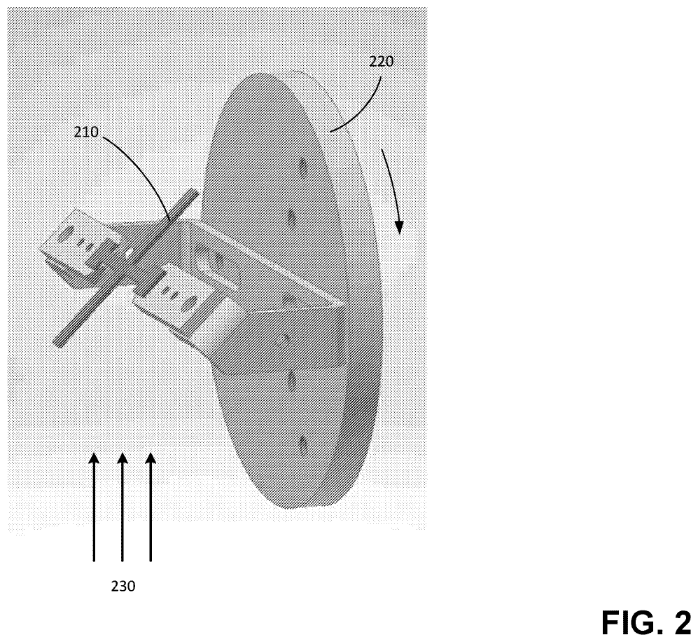

FIG. 2 illustrates a manufacturing process for a resonant structure of an electromagnetic resonator, according to some embodiments. In the example of FIG. 2, a dielectric substrate 210 formed into a desired shape for a resonant structure (e.g., resonant structure 110 shown in FIGS. 1A-1B) is held by holder 220. A thin film of material (e.g., a metal, a superconducting material) may be deposited onto the substrate via any suitable process 230, which may include physical vapor deposition (e.g., electron beam physical vapor deposition) and/or sputtering. During deposition, the holder 220 may rotate around the circular portion shown in FIG. 2 so that all exposed surfaces of the resonant structure are coated with the thin film.

In some embodiments, the substrate 210 may include a material such as silicon or sapphire. In some cases, the substrate 210 may be formed from a single-crystal dielectric. In some embodiments, the thin film deposited onto the substrate may comprise, or may consist of, aluminum, niobium, an aluminum alloy including, for instance, 6061 aluminum and 5N5 aluminum, lead, doped silicon carbide and/or a niobium-titanium alloy.

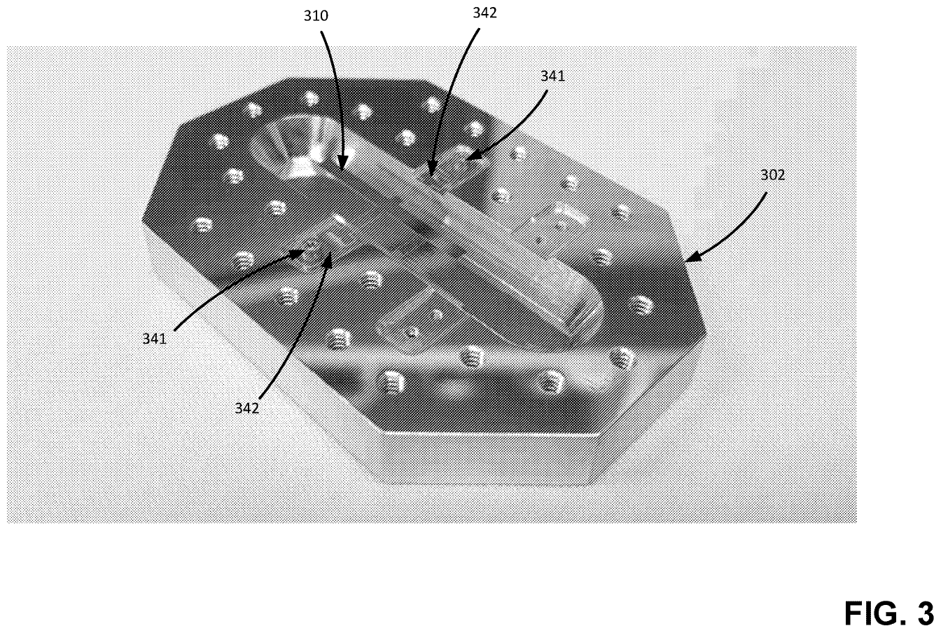

FIG. 3 is a photograph of an illustrative resonant structure arranged within part of a superconducting microwave cavity, according to some embodiments. In the example of FIG. 3, a lower portion of a microwave cavity 302 is shown with an illustrative resonant structure 310 coupled to, and mechanically supported by, the portion of the cavity 302. The resonant structure 310 was formed by laser cutting a substrate of sapphire then depositing a layer of aluminum onto the sapphire through electron beam physical vapor deposition. The lower portion of the cavity 302 is formed from 6061 aluminum and has a diamond turned upper mating surface. The resonant structure 310 is coupled to the lower portion of the cavity 302 using aluminum screws 341. In addition, clips 342 formed from a suitable material, such as beryllium-copper, are arranged between the screws and the resonant structure.

In the example of FIG. 3, the resonant structure 310 is arranged in direct mechanical contact with the lower portion of the cavity 302. In this example, the resonant structure 310 may include dielectric portions where the structure contacts the lower portion of the cavity. The clips 342 may be provided to hold the resonant structure onto the lower portion of the cavity 302, with the screws fixing one end of a respective clip onto the lower portion of the cavity.

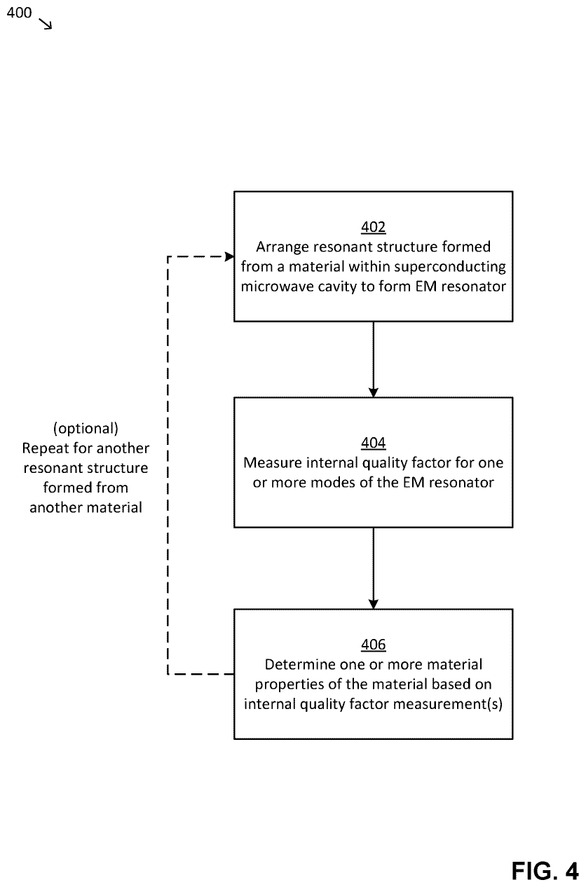

FIG. 4 is a flowchart of a method of operating an electromagnetic resonator to determine material properties of a material, according to some embodiments. As described above, some embodiments of the electromagnetic resonator described herein may be operated to produce measurements that are dependent on material properties of the materials of the resonant structure and/or the cavity. Method 400 is a method of forming a resonator and producing such measurements, then using the measurements to derive material properties, according to some embodiments.

In the example of FIG. 4, method 400 begins with act 402 in which a resonant structure is arranged within a cavity to form an electromagnetic (EM) resonator. The resonator so produced may for instance, be resonator 100 shown in FIGS. 1A-1B, or a resonator in any of the described embodiments discussed above in relation to FIGS. 1A-1B. A further example of a suitable resonator is described below. In some cases, the resonant structure may be formed from, or may comprise, the same material that the cavity is formed from (or that the interior of the cavity is coated with). For instance, the resonant structure may comprise a surface thin film of aluminum, and the cavity may also be formed from aluminum.

In act 404, the electromagnetic resonator formed in act 402 is operated (e.g., by delivering an appropriate electromagnetic signal into the cavity using a transmission line coupled to the resonator) and an internal quality factor of the cavity is measured. In some embodiments, different modes of the resonator may be excited, and the internal quality factor measured for each of the modes. These different modes may be modes with different resonant frequencies and/or modes having different resonant behavior. In some embodiments, the resonator may exhibit different types of modes that have different levels of sensitivity to different types of losses; in this case, measuring the internal quality factor for one of these modes may provide different information regarding the resonator than the internal quality factor measurement for one of the other modes.

In act 406, one or more material properties may be calculated based on the one or more internal quality factor measurements taken in act 404. An example of this process for a particular resonator design is described below. Material properties calculated in act 406 may include one or more critical temperatures, penetration depths and/or surface resistivities of the materials of the resonant structure and/or materials of the cavity. In addition, where the resonator comprises one or more dielectrics (e.g., on which the resonant structure is mounted and/or as a spacer between elements of the resonant structure), loss tangents of the dielectrics may be determined. Moreover, a seam resistance of the joint between upper and lower portions of the cavity may be determined.

In some embodiments, act 406 may comprise solving a plurality of equations that relate different expected losses to the internal quality factor for a given mode of the resonator 500. The plurality of equations may comprise values for mode-independent material properties (such as those identified above), but may be linearly related to one another, allowing the values of the material properties to be determined from the multiple measurements of the internal quality factors for each mode.

Optionally after act 406, method 400 may begin again with act 402 in which a new resonant structure is arranged within the cavity. For instance, the method may be repeated any number of times by replacing the resonant structure in the cavity with a new resonant structure to form a new resonator. In this manner, the materials of different resonant structures may be evaluated.

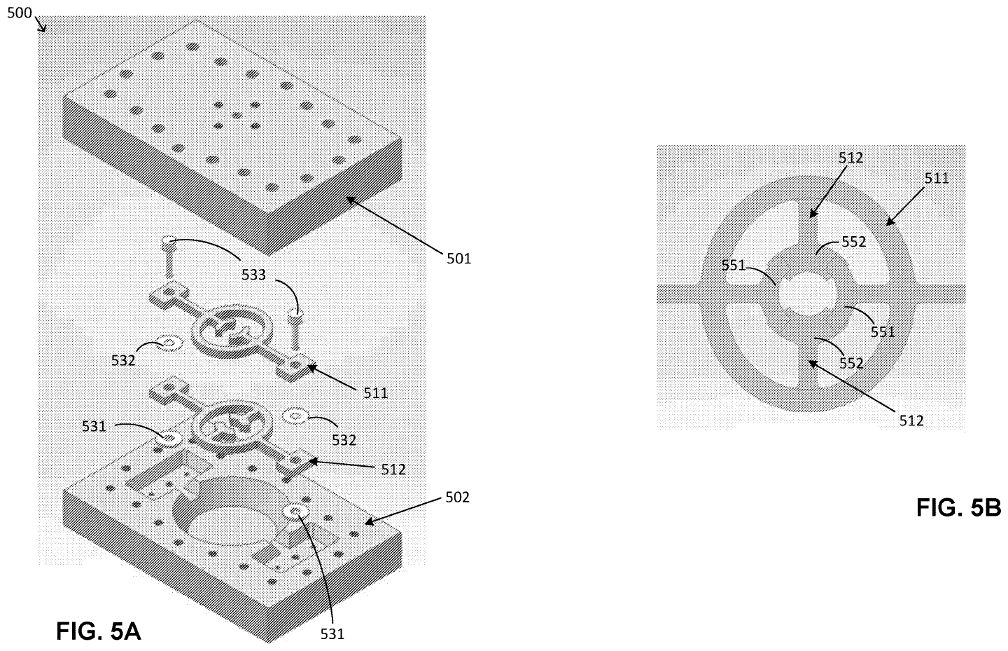

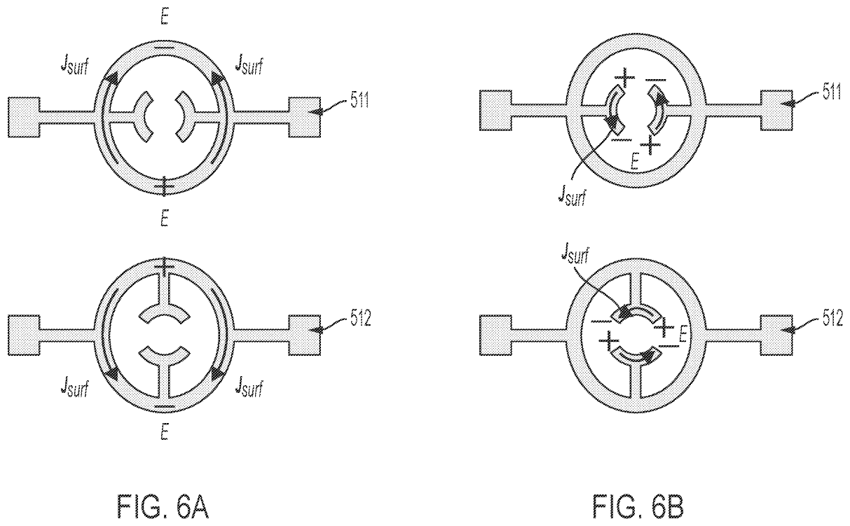

To provide an illustrative example of performing method 400, FIG. 5A depicts an exploded view of an illustrative electromagnetic resonator that includes a two-tiered resonant structure, according to some embodiments. In the example of FIG. 5A, a resonator 500 comprises a superconducting cavity formed from upper and lower portions 501 and 502. A resonant structure comprising upper element 511 and lower element 512 is arranged within the cavity and suspended over an opening in the lower portion of the cavity 502. The resonant structure 511/512 is mechanically supported by the cavity via dielectric spacers 531 and has four free ends—two in each of the elements 511 and 512—that are arranged in the interior of the circular region of each element. The upper element 511 and lower element 512 of the resonant structure are separated by dielectric spacers 532 and are attached to the lower portion of the cavity 502 using dielectric screws 533. In some embodiments, the spacers 531 and 532 may comprise PTFE washers (e.g., 0.1 mm thick washers), and the dielectric screws 533 may comprise nylon screws, although other materials may also be utilized.

A plan view of the resonant structure 511/512 is shown in FIG. 5B, according to some embodiments. The view shown in FIG. 5B focuses on just the central regions of the upper element 511 and lower element 512 to illustrate how they overlap when the resonator 500 is assembled.

As may be noted for the example of FIGS. 5A-5B, resonator 500 comprises two planar elements separated by dielectric spacers, enclosed within a cavity. The upper and lower elements 511 and 512 may, for instance, comprise metal or metallized parts. The cavity may be formed from a superconducting material, as described above. Each of the upper and lower elements 511 and 512 comprise a planar elliptical (or circular) ring, with two supporting arms connected to the outside of the ring at opposing sides of the ring, and two forks connected to the inside of the ring. The supporting arms on both planar parts may be oriented along the minor axis of the rings. The two forks on the top planar part 551 may be oriented along the major axis of the ring, whereas the two forks on the bottom planar part 552 are oriented along the minor axis of the ring. Therefore, the illustrative resonator 500 may exhibit reflectional symmetry about both axes of the elliptical rings.

The illustrative resonator 500 may be a multimode resonator that contains multiple resonance modes in the microwave frequency regime. These modes may, in some embodiments, have different sensitivity to different loss channels exhibited by the resonator. Three illustrative types of modes of the resonator 500 will now be described.

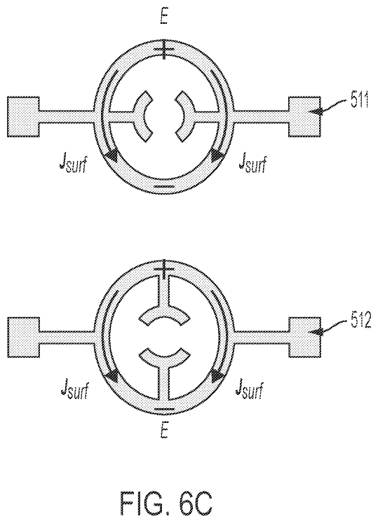

A first type of mode of resonator 500 may be referred to herein as differential whispering gallery modes (“DWG modes”). These modes, depicted by FIG. 6A, are supported by the two elliptical rings from the upper and lower elements 511 and 512. The opposite charge (labeled E in the drawings) and current (labeled J_{surf} in the drawings) distributions on the two elliptical rings confine both the electric fields and the magnetic fields within the vacuum gap between the rings, making these modes susceptible to the surface conductive loss of the superconductor as well as the dielectric loss from the surface dielectric materials. In each of FIGS. 6A, 6B and 6C, the upper and lower elements 511 and 512 of the resonant structure are shown in separate plan views but may be understood to be arranged over one another during operation, as shown in FIG. 5B.

A second type of mode of resonator 500 may be referred to herein as differential fork modes (“DF modes”). These modes, depicted by FIG. 6B, are supported by the forks from the upper and lower elements 511 and 512. The opposite charge distribution on the top forks and the bottom forks concentrates the electric fields within the vacuum gap between the forks, making these modes susceptible to the dielectric loss from the surface dielectric materials. Because the magnetic fields of these modes are not concentrated within the vacuum gap, they are comparatively less sensitive to the surface conductive loss as compared with the DWG modes.

A third type of mode of resonator 500 may be referred to herein as common whispering gallery modes (“CWG modes”). Unlike the DWG modes, these modes as depicted by FIG. 6C may have the same charge and current distributions on the two elliptical rings. Therefore, there are no electromagnetic fields within the vacuum gap between the rings. The electromagnetic fields of these modes are between the elliptical rings and the cavity surface, leading to a much larger mode volume than the DWG modes and the DF modes. Therefore, they may be comparatively less sensitive (or not sensitive) to the surface conductive loss and the surface dielectric loss but comparatively more sensitive to the seam loss from the joint of the superconducting cavity.

According to some embodiments, the inverse internal quality factors

$$\frac{1}{{Q}_{i n t}^{( i )}}$$

of the DWG modes, the DF modes, and the CWG modes may be linearly related to the surface resistivity of the cavity and resonant structure materials (which are hereinafter presumed to be superconducting materials), the loss tangent of the dielectrics 531, 532 and 533, and the seam resistance of the joint between the upper and lower portions of the cavity 501 and 502, through a participation matrix. The participation matrix may comprise participation factors of the loss channels in the corresponding modes, which are the geometric factors, the surface participation factors, and the seam admittances for the DWG modes, the DF modes, and the CWG modes. These participation factors may be determined by the electromagnetic field distribution of the modes. They can be calculated by finite-element electromagnetic simulation. If the DWG modes, the DF modes, and the CWG modes are sensitive to different loss channels, their participation factors may be linearly independent of each other. Therefore, their participation matrix is invertible, which can be used to convert the measured inverse quality factors into the surface resistivity of the superconducting cavity and resonant structure materials, the loss tangent of the dielectrics, and the resistance of the cavity seam.

For example, the internal quality factor Qᵢₙₜ⁽ⁱ⁾ for a given mode (i) may be given by:

$$\frac{1}{{Q}_{i n t}^{( i )}} = \frac{{R}_{S}}{{G}^{( i )}} + {p}_{MA}^{( i )} tan {δ}_{MA} + \frac{{y}_{seam}^{( i )}}{{g}_{seam}}$$

where R_{S} is the surface resistance of the superconducting metal from which the resonant structure and cavity are formed, G⁽ⁱ⁾ is the geometric factor for the mode (i), p_{MA}⁽ⁱ⁾ is the participation factor between the superconducting metal and the air for the mode (i), δ_{MA} is the loss tangent for the mode (i), yₛₑₐₘ⁽ⁱ⁾ is the seam admittance for the mode (i), and gₛₑₐₘ is the seam resistance. By measuring Qᵢₙₜ⁽ⁱ⁾ for each of the DWG modes, the DF modes, and the CWG modes, and by modeling values of G⁽ⁱ⁾, p_{MA}⁽ⁱ⁾ and yₛₑₐₘ⁽ⁱ⁾ for each mode, the mode-independent values of R_{S}, δ_{MA} and gₛₑₐₘ may be determined.

According to some embodiments, the DWG modes, the DF modes, and the CWG modes can be simultaneously coupled to the coupling port, enabling high precision measurement of their internal quality factors from their reflection spectrum in a single device during a single cooldown process. This may eliminate the uncertainty of the measured internal quality factors from the variations of different devices and different cooldown conditions, increasing the sensitivity to the surface resistivity, the loss tangent, and the seam resistance. In addition to the DWG modes, the DF modes, and the CWG modes, the resonator 500 may also exhibit modes sensitive to the dielectric losses from the spacers and the screws. These modes may provide a very tight bound to the loss tangent of the screws and the spacers, which could, for instance, be used to justify the insensitivity to the losses of these dielectrics in the DWG modes, the DF modes, and the CWG modes as described above.

While the above example is described in relation to resonator 500, a similar process may be envisioned for any suitable electromagnetic resonator as described herein by modeling the expected loss channels within the resonator and identifying the extent to which different modes of the resonator are expected to be sensitive to each loss channel. For instance, of the DWG modes, the DF modes, and the CWG modes, the CWG modes may be expected to be more sensitive to seam loss and therefore have a correspondingly larger value of yₛₑₐₘ⁽ⁱ⁾ than would be observed for the other two types of modes. In some cases, a particular type of mode may be insensitive to a particular loss channel, in which case a relevant value may be zero, thereby simplifying calculations to determine the unknown material properties in the equations relating the different losses to the internal quality factor.

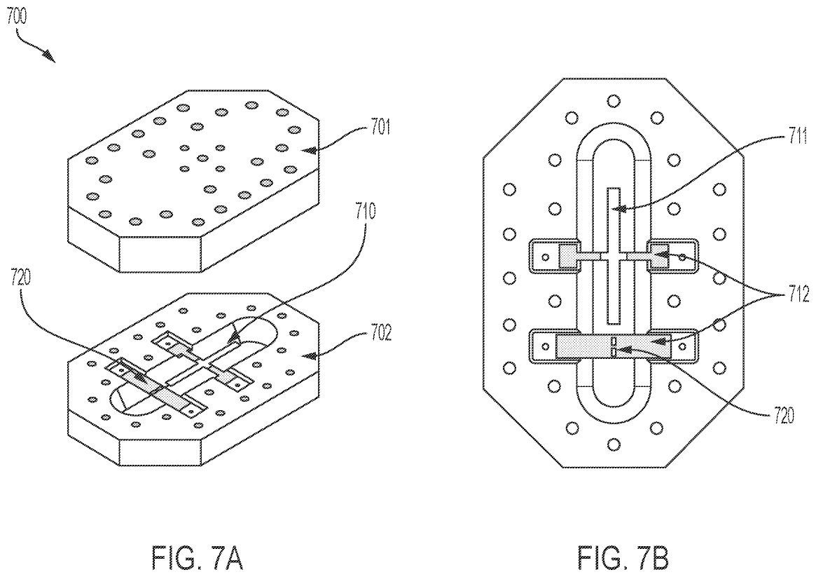

FIGS. 7A-7B depict exploded and cross-sectional plan views, respectively, of an illustrative electromagnetic resonator that includes a non-linear element, according to some embodiments. As shown in the example of FIG. 7, an electromagnetic resonator 700 may include upper and lower portions of a cavity 701 and 702, respectively, and a suspended resonant structure 710 mechanically supported by the lower portion of a cavity. The resonator 700 may also comprise a non-linear superconducting element 720, such as a Josephson junction. In some cases, the resonator 700 may comprise a transmon qubit, which comprises a Josephson junction as the non-linear superconducting element 720.

In the example of FIG. 7, the non-linear element 720 may be suspended within the cavity without being in contact with the resonant structure, but through operation of the resonator via suitable driving signals, interactions may be produced between the non-linear element and the modes (including any of the multiple modes) of the resonant structure 710 and/or cavity 701/702. In the example of FIG. 7, the resonant structure 710 includes a central region metallized with a superconducting material 711, and an exterior region at its ends 712 that formed from a low loss dielectric substrate. In some cases, the central region may comprise the same substrate coated with a thin film of the superconducting material.

In the example of FIG. 7, the suspended resonant structure 710 and the non-linear element 720 may be attached to the pedestals with spring clips or other clamping mechanisms not shown in the drawing. The design of the non-linear element 720 and the distance between the non-linear element and the resonant structure may determine the strength of coupling between a high-Q mode of the resonator 700 and the non-linear element 720. In some cases, a dispersive coupling of a few MHz may be achievable. The nonlinearity of the non-linear element 720 may in some embodiments provide for universal quantum operation of high-Q modes in the resonator 700, thereby providing for long-lived quantum memories.

In some embodiments, a single cavity may comprise multiple resonant structure 710 that are each coupled to a single non-linear element 720. This configuration may effectively provide for several high-Q devices arranged in a single package, and could be used as, for example, a quantum memory.

Having thus described several aspects of at least one embodiment of this invention, it is to be appreciated that various alterations, modifications, and improvements will readily occur to those skilled in the art.

Such alterations, modifications, and improvements are intended to be part of this disclosure and are intended to be within the spirit and scope of the invention. Further, though advantages of the present invention are indicated, it should be appreciated that not every embodiment of the technology described herein will include every described advantage. Some embodiments may not implement any features described as advantageous herein and in some instances one or more of the described features may be implemented to achieve further embodiments. Accordingly, the foregoing description and drawings are by way of example only.

Various aspects of the present invention may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, the invention may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. An electromagnetic resonator comprising:
a superconducting microwave cavity; and
a resonant structure suspended within the cavity and mechanically supported by the cavity, the resonant structure comprising at least one end that is freely suspended within the cavity.

2. The electromagnetic resonator of claim 1, wherein the resonant structure comprises:
a first portion that extends from a first side of the cavity to a second side of the cavity, the second side opposing the first side; and
a second portion that extends from the first portion and includes the at least one end that is freely suspended within the cavity.

3. The electromagnetic resonator of claim 1, wherein the resonant structure comprises a dielectric substrate.

4. The electromagnetic resonator of claim 3, wherein the dielectric substrate comprises sapphire and/or silicon.

5. The electromagnetic resonator of claim 4, wherein the resonant structure comprises a thin film of a superconducting material coating the dielectric substrate.

6. The electromagnetic resonator of claim 5, wherein the thin film completely covers the dielectric substrate.

7. The electromagnetic resonator of claim 5, wherein the superconducting material comprises aluminum.

8. The electromagnetic resonator of claim 1, further comprising a non-linear superconducting element arranged within the cavity.

9. The electromagnetic resonator of claim 8, wherein the non-linear superconducting element comprises at least one Josephson junction.

10. The electromagnetic resonator of claim 8, wherein the non-linear superconducting element is a transmon qubit.

11. The electromagnetic resonator of claim 1, wherein the resonant structure is coupled to the cavity via one or more dielectric elements.

12. The electromagnetic resonator of claim 1, wherein the resonant structure contacts the cavity.

13. The electromagnetic resonator of claim 1, wherein the resonant structure is planar.

14. The electromagnetic resonator of claim 1, wherein the resonant structure comprises a lower element and an upper element arranged over the lower element and separated from the lower element by a dielectric material.

15. The electromagnetic resonator of claim 14, wherein the lower element comprises a circular portion and wherein the at least one end that is freely suspended within the cavity is arranged within the circular portion.

16. The electromagnetic resonator of claim 14, wherein the upper element and the lower element are both planar.

17. A method of characterizing a first material using the electromagnetic resonator of claim 1, wherein the resonant structure comprises the first material, the method comprising:
measuring at least one internal quality factor of the electromagnetic resonator; and
determining at least one material property of the first material based at least in part on the measured at least one internal quality factor.

18. The method of claim 17, wherein the at least one material property includes one or more of: surface resistance, loss tangent, and seam conductance.

19. The method of claim 17, comprising measuring a first internal quality factor corresponding to a first type of mode of the electromagnetic resonator, and measuring a second internal quality factor corresponding to a second type of mode of the electromagnetic resonator.
